(19) United States
(12) Patent Application Publication
(10) Pub. No.: US 2010/0294328 A1
(43) Pub. Date: Nov. 25, 2010

(54) Photovoltaic Generator

(76) Inventors: Jia-Ting Wan, Taipei (TW); Ci-Chuan Chen, Taipei (TW)

Correspondence Address: SALLY CHANG, 3F-8 No.6, SEC. 6 CHUNG-HSIAO EAST RD., TAIPEI, TAIWAN, R.O.C. 115, TAIPEI, 115, TW

(21) Appl. No.: 12/461,636

(22) Filed: Aug. 19, 2009

(30) Foreign Application Priority Data
May 20, 2009 (TW) 098208815

(51) Int. Cl. H01L 31/042

(52) U.S. Cl. 136/244

(57) ABSTRACT

A photovoltaic generator includes at least one lighting module powered by a battery, photovoltaic module and power supply unit. The light ray emitted by said lighting module is reflected and diffused by the reflecting layer provided in an inner side of the lighting module and directed towards the surface of the photovoltaic module. The photovoltaic module transforms the light into electricity and distributes the power to electrical devices or recharges the battery to prolong the operational life of the generator by connecting with the power supply unit.

### FIELD OF THE INVENTION

The present invention relates to a photovoltaic generator, specifically, by converting the light, generated from LEDs and reflected through a reflecting layer, into electricity utilizing photovoltaic panels for supplying power to electrical devices and recharging the battery, creating a cycle for extending the time of supply.

### BACKGROUND OF THE INVENTION

A generator is a device usually for providing electricity. A conventional generator such as installed in most buildings and facilities consumes petroleum fuel, converting mechanical energy into the electricity. However, the rising fuel price increasing the cost and carbon dioxide produced by the generator raises environmental issue. Alternative generator is developed by converting sun radiation into electricity for solving aforementioned problems. The solar energy is a clean and cheap energy but its dependency of ray of sun and low efficiency limits the usage thereof in the reality.

### SUMMARY OF THE INVENTION

To solve drawbacks of both mentioned generators, a photovoltaic generator utilizing photovoltaic panels for converting light ray of LEDs into energy consists of: A photovoltaic generator consists essentially of: at least one lighting module, photovoltaic module and power supply unit. Each lighting module includes a light shade and at least one illuminating unit. A reflecting surface is applied in an inner side of said light shade; and said illuminating unit includes a power inlet to connect to a battery for illuminating said lighting module. Each photovoltaic module, such as solar panel, rigid solar panel or flexible solar panel comprises a photoelectric output for delivering electricity by converting ray from the lighting module with the photovoltaic module; and each power supply unit includes a power inlet and pluralities of power outlets, wherein said power inlet is electrically connected to the photoelectric output of the photovoltaic module, and one of the power outlets is connected electrically to the battery for recharging the battery and extending the time supply, and others power outlets are for providing electricity to electronic devices.

### BRIEF DESCRIPTION OF DRAWINGS

FIG. 1 is an exploded view demonstrating assembly of a lighting module and a photovoltaic module.

FIG. 2 is a schematic view of the lighting and photovoltaic module assembled and coupled as wholeness.

FIG. 3 is a cross sectional view of FIG. 2 along line III-III.

FIG. 4 is a cross sectional view of another embodiment of the assembly said lighting and photovoltaic module.

FIG. 5 is a schematic view demonstrating the storage of pluralities of unit as shown in FIG. 2 in a cabinet.

FIG. 6 is a schematic view of the cabinet.

FIG. 7 is a functional block diagram of the present invention.

FIG. 8 is a functional block diagram of another embodiment of the present invention.

FIG. 9 is a schematic view demonstrating the application of the present invention in an electric automobile.

### DETAIL DESCRIPTION OF PREFERRED EMBODIMENTS

Reference will now be made in detail to embodiments of the invention which are illustrated in the accompanying drawings.

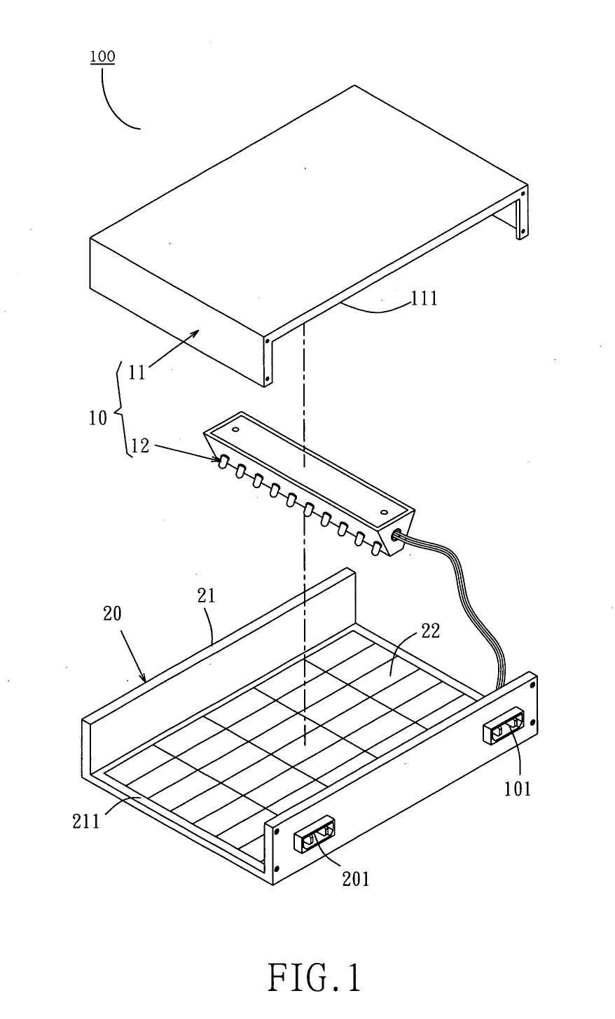

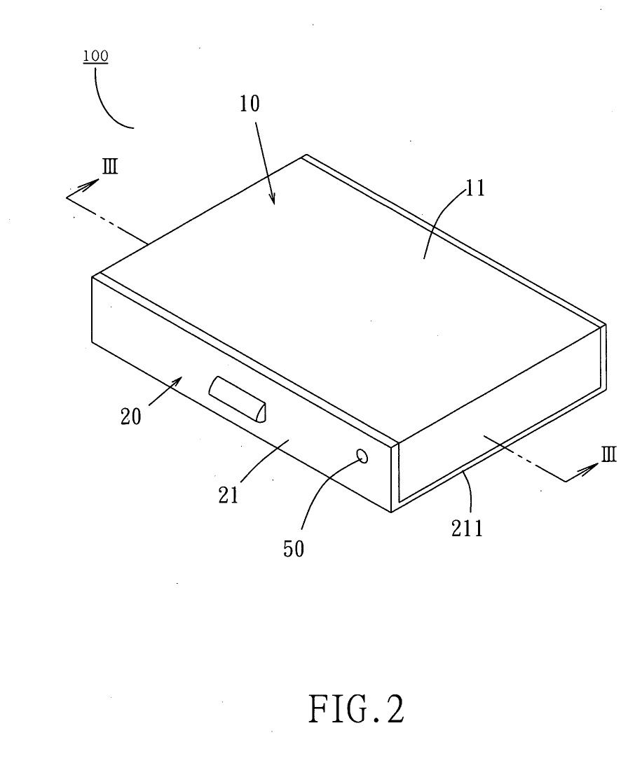

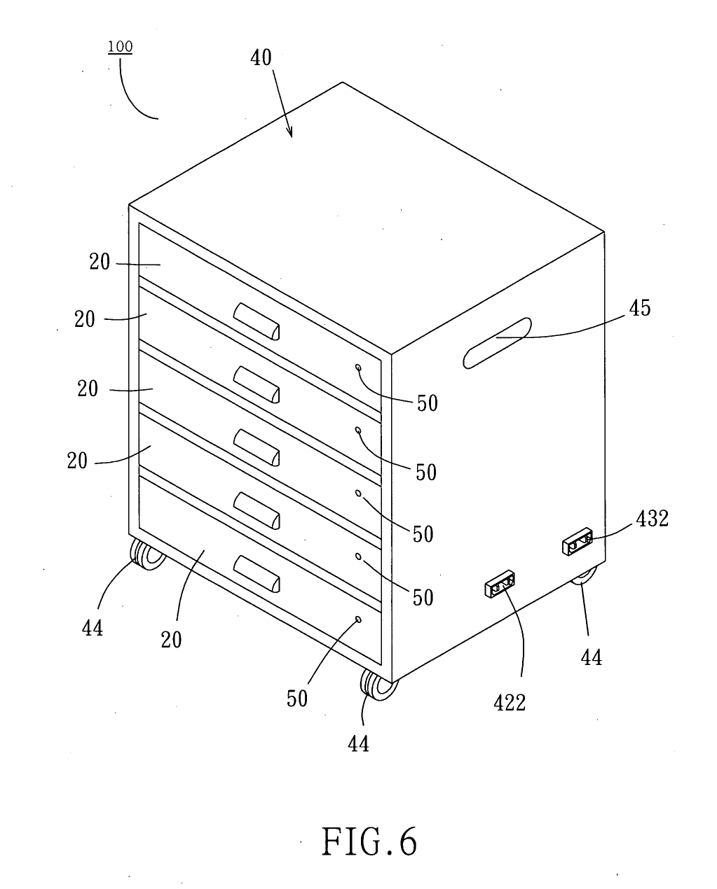

As shown in FIGS. 1-9, a photovoltaic generator (100) consists essentially of: at least one lighting module (10), photovoltaic module (20) and power supply unit (30). Each lighting module (10) includes a light shade (11) and at least one illuminating unit (12). A reflecting surface is applied in an inner side of said light shade; and said illuminating unit (12) includes a power inlet (101) to connect to a battery (13) for illuminating said lighting module. Each photovoltaic module (20), such as solar panel, rigid solar panel or flexible solar panel comprises a photoelectric output (201) for transmitting electricity by converting ray from the lighting module with the photovoltaic module. Each power supply unit (30) includes a power inlet (31) and multiple power outlets (32, 33), wherein said power inlet (31) is electrically connected to the photoelectric output (201) of the photovoltaic module (20), and one of the power outlets (32) is connected electrically to the battery (13) for recharging and extending the time supply, and others power outlets are set for providing electricity to electronic devices.

By reflecting the light produced by multiple illuminating units (12) towards the photovoltaic module (20) with the reflecting surface provided at inner side of the light shade (11), the module (20) transforms the light emission into electricity for being consumed by the electrical devices and recharging the battery (13) simultaneously, to prolong the operational life of the battery.

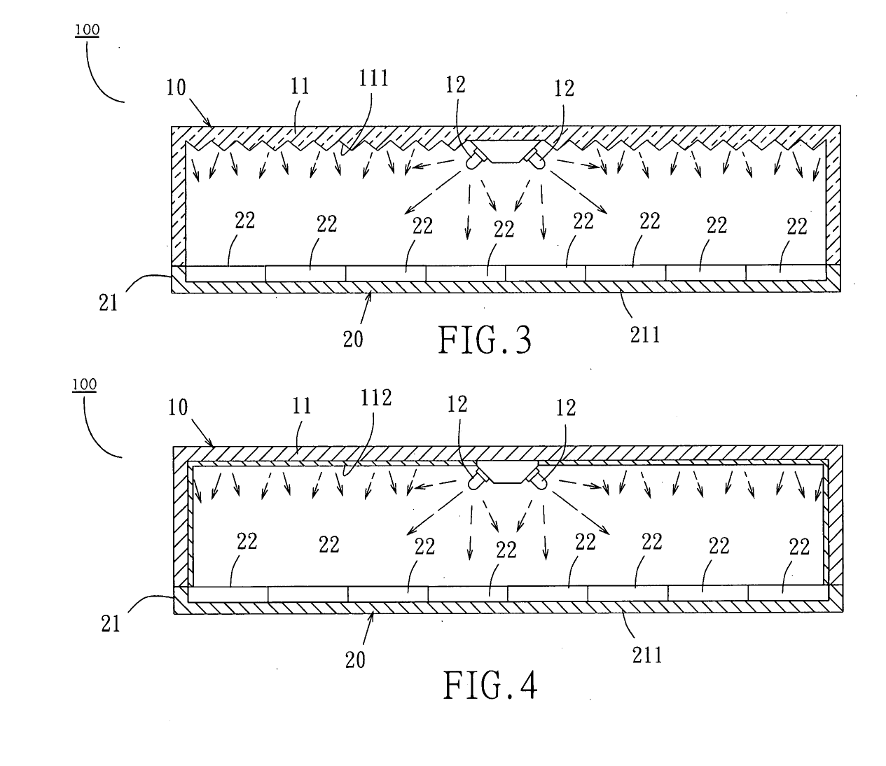

Referring to FIGS. 3 and 4, the reflecting layer provided at inner side of the light shade (11) can be made of a serrated surface (111), application of a reflecting membrane (112) or coating of metal such as aluminum, nickel, zinc or chromium. By utilizing said reflecting layer, the light direction emitted from the illuminating unit (12) can be diffused to increase the conversion rate of the photovoltaic module (20). The unit (12) can be selected from a light emitting diode (LED), an organic light emitting diode (OLED) or other light emitting unit which consumes less power to bring greater efficiency to the invention.

Said photovoltaic module (20) includes a housing (21) which comprises a carrier (211). Multiple panels (22) are arranged on a surface of said carrier (211). The panel (22) is selected from existing solar panels, such as single-crystal silicon solar panel, multi-crystalline silicon solar panel and coating solar panel. The panel (22) can also be a rigid or thin-film panel, and the shape thereof is not limited. The light shade (10) is disposed and fixed on a top of said carrier (211), coupling said lighting module (10) and photovoltaic module (20) as a whole and covered said panels (22) therein.

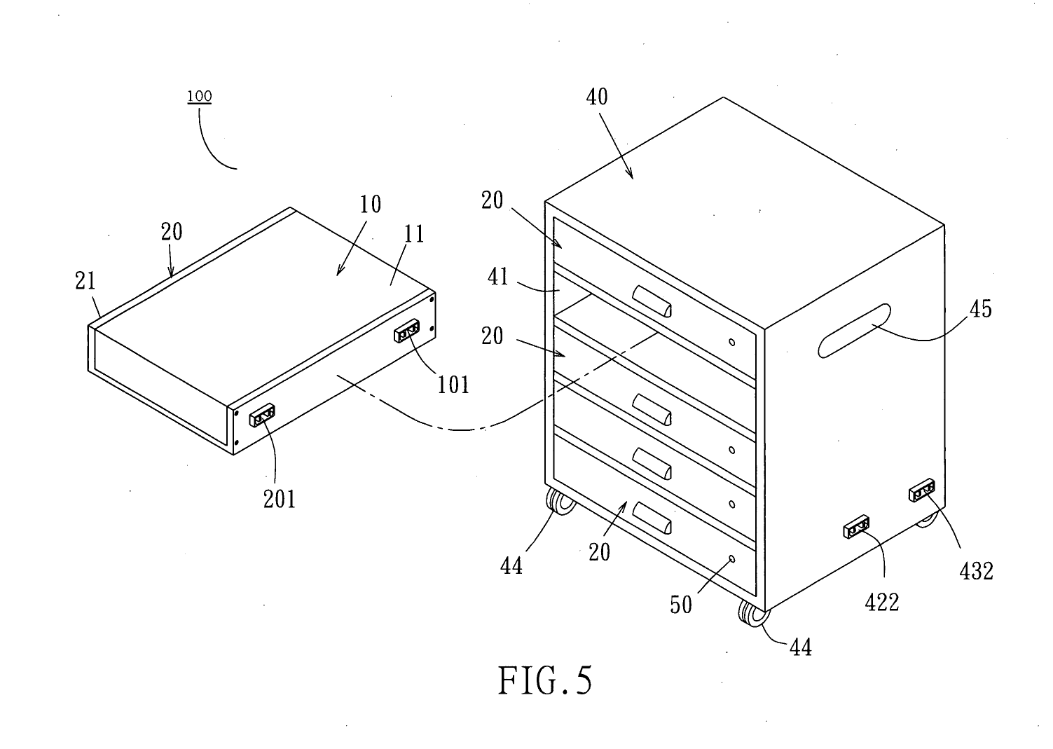

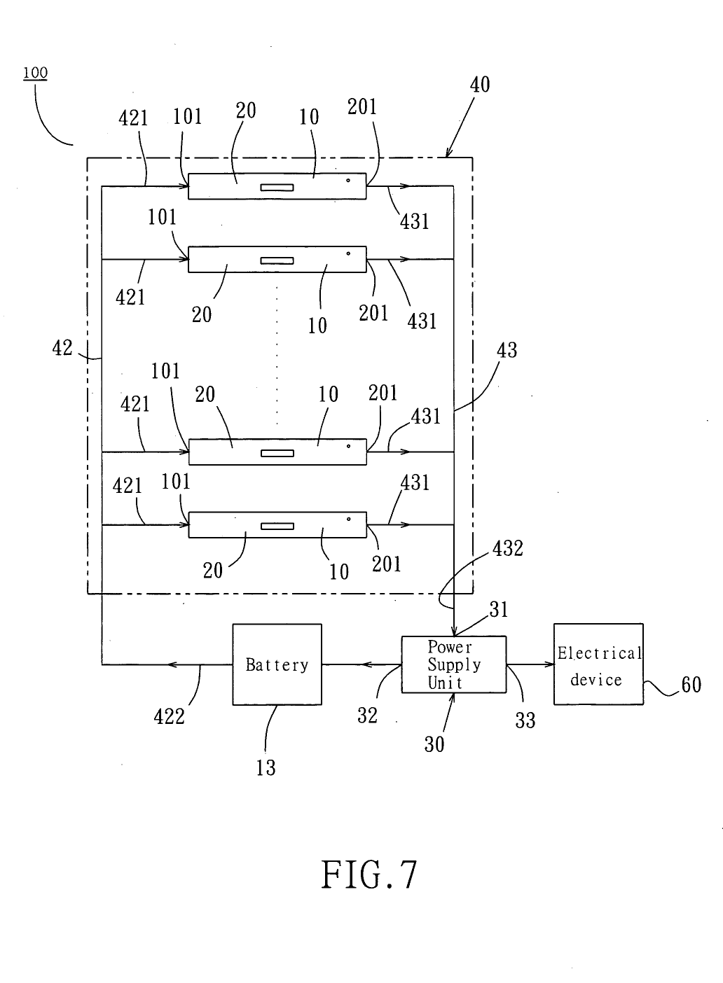

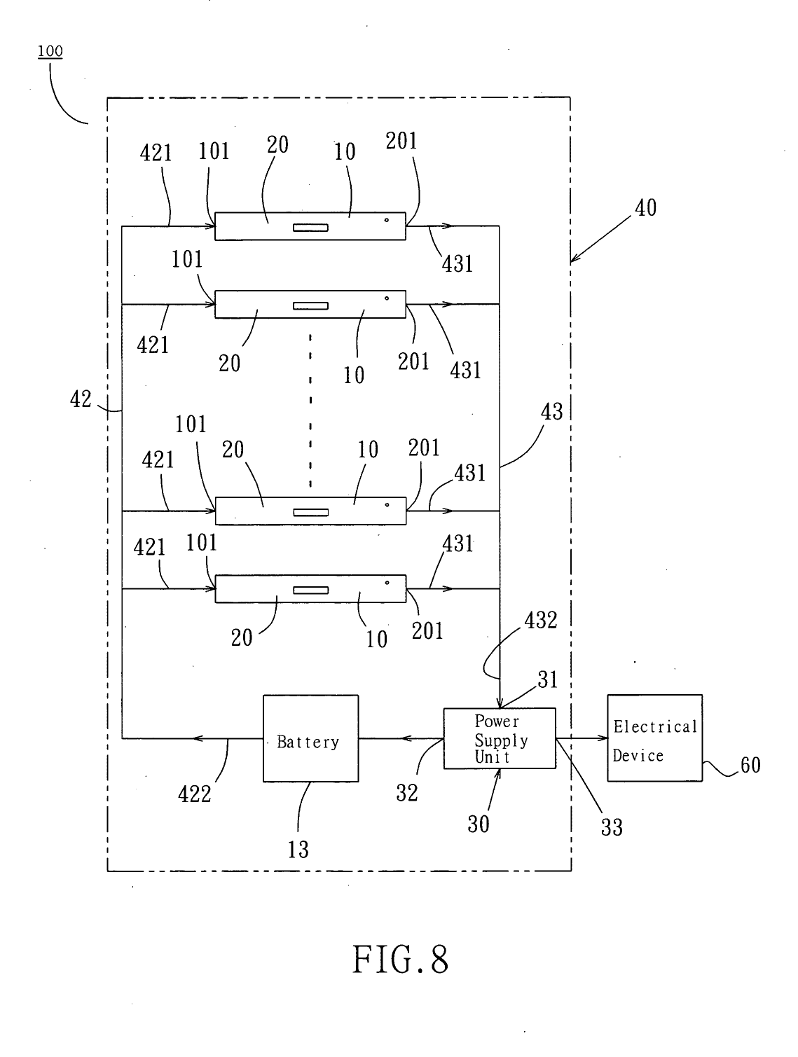

As illustrated in FIGS. 5-7, said cabinet (40) is composed of pluralities of containers (41), and a set of said lighting module and photovoltaic module assembled as wholeness is placed in each container (41). At least one first and second power cables (42, 43) are incorporated in the cabinet. The first power cable (42) includes pluralities power outputs (421) at an end and a power input (422) at another end. Each of outputs (421) connects electrically to the power inlet (101) of the lighting module (10) of each container (41), and said power input (422) is connected electrically to the battery (13). The second power cable (43) also comprises multiple power inputs (431) at an end and a power output (432) at another end, each of inputs (431) connects electrically to the power outlet (201) of the photovoltaic module (20) of each container (41), and said power output (432) is connected electrically to the power inlet (31) of said power supply unit (30). Thus, each set of the lighting and photovoltaic modules stored in the container (41) can be interconnected with each other in a series or parallel circuit. In FIG. 7, a way of connection is shown by having the battery (13) and power supply unit (30) outside of the cabinet (40) and in FIG. 8, an alternative way of installation, wherein a cabinet (40) incorporated the battery (13) and power supply unit (30) is illustrated.

Further, four sets of rollers (44) can be provided on the bottom and a handle (45) can be provided on two relative sides of the cabinet (40) for the transportation.

Referring to FIG. 5, an indicating light (50), driven and illuminated when the lighting module (10) and photovoltaic module (20) are switched on can be provided on the exterior of each housing (21) contained in the cabinet (40) for indicating status of the lighting and photovoltaic modules (10, 20).

As illustrated in FIG. 3-4 and 7-8, the function of the photovoltaic generator is described hereafter. Light emitted from the illuminating unit (12) is reflected and diffused by the reflecting surface provided inside the lighting module (10) and directed to the surface of the panel (22) of the photovoltaic module (20). The light ray is transformed by the panel (22) into power and transmitted to the power supply unit (30). The power is transformed and regulated; part of the energy is consumed by the electrical device (60) and another portion is utilized to recharge the battery (13), creating a recycle loop to extend the operational life of the device.

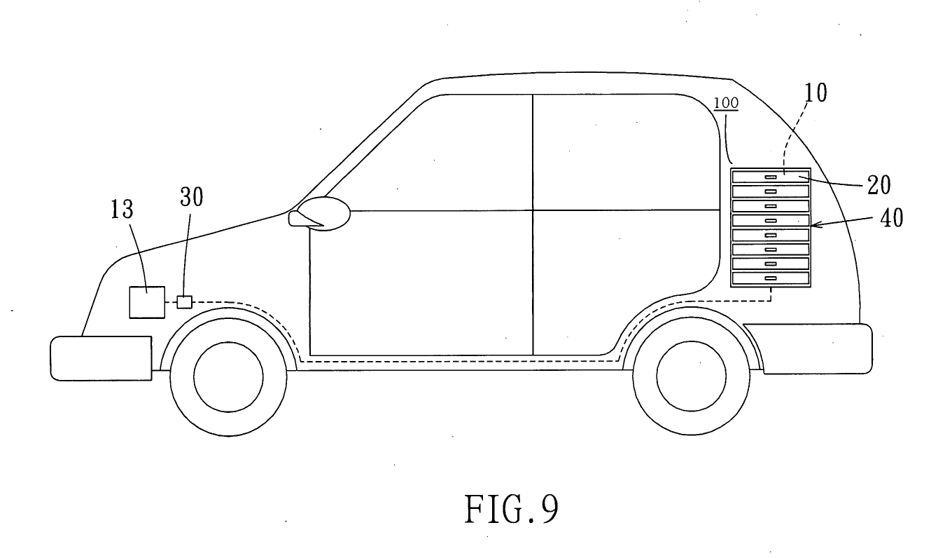

In FIG. 9, said generator (100) can also be utilized in an electric automobile, wherein the battery (13) and power supply unit (30) are placed in the front of the vehicle and the generator (100) is provided in the rear side. The power generated by the generator is delivered back to the battery (13) by a power cable, recharging the battery (13) while the automobile is in function.

What is claimed is:

1. A photovoltaic generator consist essentially of:
At least one lighting module, which includes a light shade and at least one illuminating unit; a reflecting surface is applied in an inner side of said light shade; and said illuminating unit includes a power inlet to connect to a battery for illuminating said lighting module;
At least one photovoltaic module, which comprises a photoelectric output for delivering electricity generated by converting ray from the lighting module with the photovoltaic module;
At least one power supply unit, which includes a power inlet and pluralities of power outlets, wherein said power inlet is electrically connected to the photoelectric output of the photovoltaic module, and one of the power outlets is connected electrically to a battery for recharging and others power outlets are for supplying electricity to a plurality of electronic devices.

2. A photovoltaic generator of claim 1, wherein said reflecting surface is an indented surface.

3. A photovoltaic generator of claim 1, wherein said reflecting surface is provided with a reflecting membrane.

4. A photovoltaic generator of claim 1, wherein said reflecting surface is coated with one of following materials: Aluminum, Nickel, Zinc or Chromium.

5. A photovoltaic generator of claim 1, wherein said illuminating unit is a light emitting diode (LED) or an organic light emitting diode (OLED).

6. A photovoltaic generator of claim 1, wherein said photovoltaic generator is provided with a portable device as a portable generator, in a power room or in an automobile for supplying electricity.

7. A photovoltaic generator of claim 1, wherein said photovoltaic module includes a housing which comprises a carrier; pluralities of panels are arranged on a surface of said carrier; the light shade is disposed and fixed on a top of said carrier, coupling said lighting module and photovoltaic module as a whole and covered said panels therein.

8. A photovoltaic generator of claim 1, wherein said panel is selected from one of following: single-crystal silicon solar panel, multi-crystalline silicon solar panel and coating solar panel.

9. A photovoltaic generator of claim 1, wherein said lighting module and photovoltaic module are integrated into a whole and is disposed into a cabinet, and a handle is provided on two relative sides of said cabinet.

10. A photovoltaic generator of claim 9, wherein said cabinet comprises a plurality of containers, and said integrated lighting and photovoltaic module is placed in said container; at least one first and second power cables are incorporated in the cabinet; said first power cable includes a plurality of power outputs at an end and a power input at another end, each of the outputs connects electrically to the power inlet of the lighting module of the each container, and said power input of the first power cable is connected electrically to the battery; said second power cable also comprises a plurality power outputs at an end and a power input at another end, each of inputs connects electrically to the power outlet of the photovoltaic module of each container, and said power output of the second power cable is connected electrically to the power inlet of said power supply unit.

11. A photovoltaic generator of claim 9, wherein said battery and power supply units are provided in one of following location: inside of said cabinet or outside of said cabinet.

12. A photovoltaic generator of claim 9, wherein each of containers incorporates the lighting module and photovoltaic module is connected in following methods: series circuit or parallel circuit.

13. A photovoltaic generator of claim 9, wherein at least four rollers are attached on a bottom of said cabinet.

14. A photovoltaic generator of claim 1, wherein said photovoltaic generator further includes an indicating light, driven and illuminated when the lighting module and photovoltaic module are switched on.
